(19) United States
(12) Patent Application Publication
(10) Pub. No.: US 2025/0238579 A1
(43) Pub. Date: Jul. 24, 2025

(54) ADAPTIVE GEOMETRIC MODELING METHOD FOR ASSEMBLED THIN-WALLED COMPONENT STRUCTURES ORIENTED TO INTEGRATION OF MODELING, ANALYSIS AND OPTIMIZATION

(71) Applicant: DALIAN UNIVERSITY OF TECHNOLOGY, Dalian, Liaoning (CN)

(72) Inventors: Peng HAO, Dalian, Liaoning (CN); Yu WANG, Dalian, Liaoning (CN); Lingzhi JIN, Dalian, Liaoning (CN); Bo WANG, Dalian, Liaoning (CN)

(21) Appl. No.: 18/697,989

(22) PCT Filed: Nov. 16, 2023
(86) PCT No.: PCT/CN2023/131902

§ 371 Date: Apr. 2, 2024

(30) Foreign Application Priority Data
Feb. 1, 2023 (CN) 202310050219.1

(51) Int. Cl. G06F 30/23; G06T 17/30

(52) U.S. Cl. CPC G06F 30/23; G06T 17/30

(57) ABSTRACT

An adaptive geometric modeling method for assembled thin-walled component structures oriented to integration of modeling, analysis and optimization, includes firstly, using a multi-level NURBS-based free-form deformation (MNFFD) technique to realize accurate geometric modeling of an assembled thin-walled component structure; secondly, establishing a modeling-analysis unified model suitable for isogeometric analysis of the assembled thin-walled component structure based on an MNFFD method; finally, establishing a modeling-analysis-design unified model suitable for collaborative design of a shape and a stiffened layout of the assembled thin-walled component structure based on the MNFFD method. The present invention fundamentally solves the modeling robustness problem of gaps and overlaps between thin-walled components due to the lack of accurate topological consistency in traditional modeling methods, provides a new tool for optimization design of engineering thin-walled structures. MNFFD is used, so that the geometric dimension reduction transformation from 3D design domain to 2D design domain can be realized.

### TECHNICAL FIELD

The present invention relates to the technical field related to structural mechanics and digital design, and particularly relates to an adaptive geometric modeling method for assembled thin-walled component structures oriented to integration of modeling, analysis and optimization.

### BACKGROUND

Assembled thin-walled component structures, typically composed of two or more simpler components (e.g., stiffened plates and shell structures, multi-walled and multi-ribbed structures, sandwich structures, and thin-walled lattice structures), have been widely used in various engineering fields because of their unique advantages, particularly in high specific stiffness. Structural optimization is an important tool in product design, and the development level of structural optimization technology is directly related to the bearing performance and lightweight of a structure. In a previous design system, a CAD system is used for modeling, a CAE system is used for finite element analysis, and data exchange between the two systems needs to be conducted through a mesh model constructed semi-automatically. For a model system with a complex assembly relationship, such a design process is not only inefficient, but also difficult to be automated. In recent years, the problems have been solved by isogeometric analysis, which makes it possible to develop a large-scale seamless integrated analysis and design platform. This is because CAD interpolation models are directly applied to geometric and physical fields in isogeometric analysis, which integrates modeling and analysis into a unified model, and achieves seamless integration of the CAD system and the CAE system. Although isogeometric analysis has achieved great success in many fields of science, creating a complete analytical model directly by the CAD system is still not available in most cases, especially when dealing with an assembled thin-walled component structure which is commonly seen in engineering; this is mainly because modeling by NURBS will be severely limited by a tensor product structure thereof. A complex model can only be generated by boolean operations, which leads to a fact that the complex model usually requires a large number of NURBS patches, and a large number of trimming curves are used in the NURBS patches. Therefore, global discretization based on NURBS cannot be directly applied to isogeometric analysis.

At the present stage, two kinds of solutions are mainly used, both of which aim to achieve truly automated analysis. The first kind is to solve the problem from an analytical perspective. A finite element method is an extension of a classical finite element method, a main idea of which is to extend the boundaries of a physical domain to a larger embedded domain with a simple geometric structure, which can be discretized by a structured mesh. The finite element method is mainly oriented to the analysis of 3D structures and avoids re-parameterization of NURBS solids. For a thin-walled structure, a well-known modeling method in the CAD system is a B-Rep model based on NURBS. The second kind is to regard the problem from a modeling perspective. A re-parameterization method can be used to transform a trimmed B-Rep model into an untrimmed NURBS surface. Some scholars have proposed to re-parameterize CAD embedding by global reconstruction guided by a frame field. An obtained geometric shape can be used for design and analysis without the need of further mesh and geometric processing. By reconstructing an untrimmed NURBS model, application of IGA in a complex engineering object is more simple and convenient.

In fact, NURBS modeling rules will not only affect analysis, but also bring difficulties to structural optimization. In an analytical design workflow, analysis only needs to be conducted once from a geometric model to an analytical model; whereas in a design optimization workflow, the geometric model needs to be changed according to design variables, an analytical program needs to be invoked repeatedly in a structural optimization framework, and both the control and the structural analysis of the geometric model need to be automated. Multi-level stiffened thin-walled structures, which can be regarded as a kind of assembled structures, have a strict assembly relationship between their thin-walled components. In a design process of a stiffened structure, when a shape is modified, how to ensure an original assembly relationship is a difficult point. The positions of control points of NURBS curves, surfaces and solids are often used as design variables in an isogeometric optimization paradigm, and shape control can be achieved with a small number of design variables; however, this also brings a series of problems; for example, when a control point is moved, the original assembly relationship between the thin-walled components will be destroyed. In conclusion, a design analysis optimization workflow requires models that are suitable both for analysis and optimization. For this reason, some scholars have proposed an interactive geometric modeling and analysis platform based on parametric design and an implicit modeling paradigm. Implicit modeling is a trimmed expression method, which is to define a display range by curves in a parameter domain of a NURBS curved surface, and can be understood as a mapping relationship from a 2D parameter domain to a 3D physical domain.

Another method using the same idea is a free-form deformation (FFD) technique, the basic idea of which is to embed an object into a parameterized solid. When the parameterized solid is deformed, deformation is transferred to the embedded object, which ensures that the original assembly relationship remains unchanged when the deformation occurs. Compared with a classical FFD algorithm, NFFD has greater flexibility and controllability. The same effect can be achieved by embedding the object into the parameter space of NURBS surfaces and solids. In previous studies, FFD and NFFD have had only one level of mapping relationship. For a complex engineering thin-walled structure, it is often necessary to nest multi-level thin-walled components. Therefore, a multi-level NFFD method, namely an MNFFD method, is proposed to realize integrated geometric modeling of the assembled the thin-walled component structure.

### SUMMARY

The present invention mainly solves the technical problems of poor modeling analysis accuracy and low optimization efficiency of assembled thin-walled component structures in the prior art. In a previous design system, data exchange between a CAD system and a CAE system needs to be conducted through a mesh model constructed semi-automatically; for a model system with a complex assembly relationship, such a design process is not only inefficient, but also difficult to automate; in addition, a large number of trimmed curved surfaces are used in an existing B-rep modeling method, which seriously affects the geometric accuracy and water tightness of the model. With respect to the above problems, the present invention proposes an adaptive geometric modeling method oriented to integration of modeling, analysis and optimization for assembled thin-walled component structures to realize integrated geometric modeling of assembled thin-walled component structures, so as to achieve the purposes of improving modeling accuracy of the assembled thin-walled component structures, improving calculation efficiency and calculation accuracy of analytical design, and shortening product design cycles.

To achieve the above purposes, the present invention adopts the following technical solution:

An adaptive geometric modeling method for assembled thin-walled component structures oriented to integration of modeling, analysis and optimization, comprising the following steps:
Step 100: using a multi-level NURBS-based free-form deformation (MNFFD) technique to realize accurate geometric modeling of an assembled thin-walled component structure, which comprises the following sub-steps:
Step 101: using a NURBS-based free-form deformation (NFFD) technique to establish implicit characterization relationships of a complex thin-walled structural assembly, specifically including the following two mapping relationships: first, embedding a NURBS curve into a parameter space of a NURBS curved surface, i.e., mapping from a 2D parameter space R² (ξ₁, ξ₂) to a 3D physical space R³ (x, y, z); second, embedding a NURBS curved surface into a parameter space of a NURBS solid, i.e., mapping from a 3D parameter space R³ (ξ₁, ξ₂, ξ₃) to a 3D physical space R³ (x, y, z). By embedding an object into the parameter space of the NURBS curved surface or the NURBS solid, the implicit geometric definitions of the curve in the curved surface and the curved surface in the solid are obtained.
Step 102: allowing multi-level and composite mapping of a structure and proposing an MNFFD method according to the two mapping relationships mentioned in step 101 on the basis of an original NFFD method of single-level mapping to establish the implicit characterization relationships of an assembled thin-walled component structural assembly based on MNFFD. The multi-level mapping relationship of MNFFD enables a nested model to satisfy assembly relationships and geometric constraints between different thin-walled components, and finally realize accurate geometric modeling of the assembled thin-walled component structure.
Step 200: establishing a modeling-analysis unified model suitable for isogeometric analysis of the assembled thin-walled component structure based on the MNFFD method, which comprises the following sub-steps:
Step 201: deriving theoretical formulas of a 6-degree-of-freedom degenerated shell element and a 6-degree-of-freedom degenerated beam element based on an MNFFD mapping model according to an isogeometric paradigm.
Step 202: establishing a coupling relationship of NURBS curved surface patches by a domain decomposition method in isogeometric analysis based on MNFFD to realize propagation of solutions between curved surfaces or mapping curved surfaces.
Step 300: establishing a modeling-analysis-design unified model suitable for collaborative design of a shape and a stiffened layout of the assembled thin-walled component structure based on the MNFFD method, which comprises the following sub-steps:
Step 301: in optimization design of a thin-walled structure, establishing a modeling-analysis-design integrated model based on the MNFFD method, transforming a design space from a 3D physical space to a 2D or 3D standard parameter space, and conducting collaborative optimization of a shape and a stiffened layout of a shell. With respect to shape optimization of the assembled thin-walled component structure, using a mapping curved surface in an MNFFD model to represent a skin, a ribbed plate, a stiffener or other structures, embedding the mapping curved surface into a 3D NURBS solid, changing a shape of a surrounding NURBS solid by moving control points thereof or modifying a weight value, and transferring deformation directly to an object geometry represented by the mapping curved surface.
Step 302: in the design of the stiffened layout of the assembled thin-walled component structure, conducting parametric design of the stiffened layout in two parts: optimization of shapes of stiffener curves and optimization of the stiffened layout. The shapes of the stiffener curves are defined by quadratic NURBS mapping curves, and each curve is represented by at least three control points; with respect to the spacing of the stiffener curve family, a geometric series function is defined to represent the spacing among the control points of the stiffener curves.

Further, the domain decomposition method in the step 202 includes a penalty method, a Lagrange multiplier method and a Nitsche's method.

The innovativeness analysis and beneficial effects of the present invention are as follows:

The present invention provides an MNFFD geometric modeling method suitable for assembled thin-walled component structures, which fundamentally solves the modeling robustness problem of gaps and overlaps between thin-walled components due to the lack of accurate topological consistency in traditional modeling methods, unifies expression forms of a design model, an analysis model and an optimization model based on an isogeometric paradigm, provides a new tool for optimization design of engineering thin-walled structures, and is expected to greatly improve product design accuracy and shorten development cycle. A multi-level nested composite spline structure in MNFFD allows deformation to be transferred between the thin-walled components, so that the geometric dimension reduction transformation from 3D design domain to 2D design domain is realized, the problem of adaptive updating of a design model is solved, and the design domain decoupling of an assembled thin-walled component structure with a complex assembly relationship is realized.

In the present invention, first, a NURBS-based free-form deformation (NFFD) technique is used to establish implicit characterization relationships of a complex thin-walled structural assembly; and by embedding an object into the parameter space of the NURBS curved surface or the NURBS solid, the implicit geometric definitions of the curve in the curved surface and the curved surface in the solid are obtained. Next, multi-level and composite mapping of a structure is allowed and an implicit MNFFD modeling method suitable for stiffened thin-walled structures with multi-level assembly relationships is proposed on the basis of an original NFFD method of single-level mapping. The implicit modeling method can effectively avoid the problem of water tightness, and is beneficial to improving the modeling and analysis accuracy based on the MNFFD model. The multi-level mapping relationship of MNFFD enables a nested model to satisfy assembly relationships and geometric constraints between different thin-walled components, and finally realize accurate geometric modeling of the assembled thin-walled component structure. In order to realize the modeling-analysis unified model, the present invention extends the MNFFD model to the isogeometric paradigm, and realizes isogeometric analysis based on the MNFFD model. The 6-degree-of-freedom degenerated shell element and the 6-degree-of-freedom degenerated beam element are used in the isogeometric analysis, and a series of theoretical formulas of mapping elements are derived for mapping curved surfaces and mapping curves based on MNFFD modeling, which can solve the key problems such as coupling of multiple surface patches simultaneously. With respect to the design of the assembled thin-walled component structure, a modeling-analysis-design integrated model is established based on the MNFFD method, and the design space is transformed from a 3D physical space to a 2D or 3D standard parameter space, so that the design model is simplified, and the difficulty of setting design variables is reduced. In addition, the mapping curved surfaces and the mapping curves, as important thin-walled components in the MNFFD model, are well fitted with the model of assembled thin-walled component structures with multi-level nested relationships, wherein the mapping curves can be used for characterizing stiffeners and trimming curves, and the mapping curved surfaces can be used for characterizing skins, ribbed plates and stiffeners. At the same time, the implicit modeling method based on MNFFD provides a coupling relationship between thin-walled components, so that deformation can be transferred between the thin-walled components, and the original assembly relationship will not be destroyed by any shape change of the thin-walled components, which is very beneficial to model updating in an optimization design process. All the above factors make the geometric modeling of the thin-walled structure based on MNFFD have more obvious advantages in design than explicit splines and discrete meshes. The present invention is expected to be one of the main geometric modeling methods for assembled thin-walled component structures in the fields of aerospace, ship, automobile, civil construction, etc.

### DESCRIPTION OF DRAWINGS

FIG. 1 is a schematic diagram of solid definition based on 2D NFFD, wherein (a) is a parameter space of an embedded curve; (b) is an embedded curve embedded into a parameter space of a NURBS curved surface; and (c) is a mapping curve in a NURBS curved surface.

FIG. 2 is a schematic diagram of solid definition based on 3D NFFD, wherein (a) is a parameter space of an embedded curved surface; (b) is an embedded curved surface embedded into a parameter space of a NURBS solid; and (c) is a mapping curved surface in a physical space of a NURBS solid.

FIG. 3 is a flow diagram of a stiffened structure constructed by MNFFD, wherein (a) is a parameter space of an embedded curve; (b) is an embedded curve embedded into a parameter space of an embedded curved surface; (c) is a mapping curve in a physical space of an embedded curved surface and an embedded curved surface embedded into a parameter space of a NURBS solid; (d) is a mutual mapping curve in a mapping curved surface; and (e) is a geometric model of a stiffened structure.

FIG. 4 is schematic diagram of solving a formula of a mapping shell element.

FIG. 5 is a schematic diagram of geometric information of a mapping stiffener, wherein (a) is a definition of a direction vector of the stiffener in a physical space; and (b) is a definition of a cross-section of the stiffener.

FIG. 6 is a schematic diagram of controlling a shape of a mapping curved surface by modifying positions of control points of a NURBS solid.

FIG. 7 is a schematic diagram of controlling a shape of a mapping curved surface by modifying a weight value of control points of a NURBS solid.

FIG. 8 is a schematic diagram of definitions of two stiffener curve families in a parameter space.

FIG. 9 is a schematic diagram of representing a spacing of a stiffener curve by a geometric series function, wherein (a) is a definition of uniform control points; (b) is a definition of sparse-dense-sparse control points (c) is a definition of dense-sparse-dense control points; and (d) is a definition of sparse-dense control points.

FIG. 10 is an initial model of a roof, wherein (a) shows two stiffener curve families defined by embedded curves embedded into a parameter space of an embedded curved surface; (b) is an embedded curved surface embedded into a parameter space of a NURBS solid; (c) show a mapping curved surface and a mutual mapping stiffener in a physical space of a NURBS solid; and (d) is a rendering perspective view of the roof.

FIG. 11 is an initial model displacement cloud image fixedly constrained by four boundaries.

FIG. 12 shows optimization of a shape and a stiffened layout of a curved surface, wherein (a) is an iterative curve for collaborative optimization of a shape and a stiffened layout of a curved surface; (b) shows optimization configuration and analysis results when an algebraic value at mark A in (a) is 4; (c) shows optimization configuration and analysis results when an algebraic value at mark B in (a) is 14; and (d) shows optimization configuration and analysis results when an algebraic value at mark C in (a) is 25.

FIG. 13 shows a shape and a stiffener layout of a stiffened roof after optimization, wherein (a) is a 2D embedding domain; (b) is a 3D embedding domain; (c) is a structural geometry domain; (d) is a 3D rendering picture; and (e) is a rendering picture of a substructure.

### DETAILED DESCRIPTION

To make the technical problem solved, the technical solution adopted and the technical effect achieved by the present invention more clear, the present invention will be further described below in detail in combination with the drawings and the embodiments. It should be understood that the specific embodiments described herein are only used for explaining the present invention, not used for limiting the present invention. In addition, it should be noted that for ease of description, the drawings only show some portions related to the present invention rather than all portions.

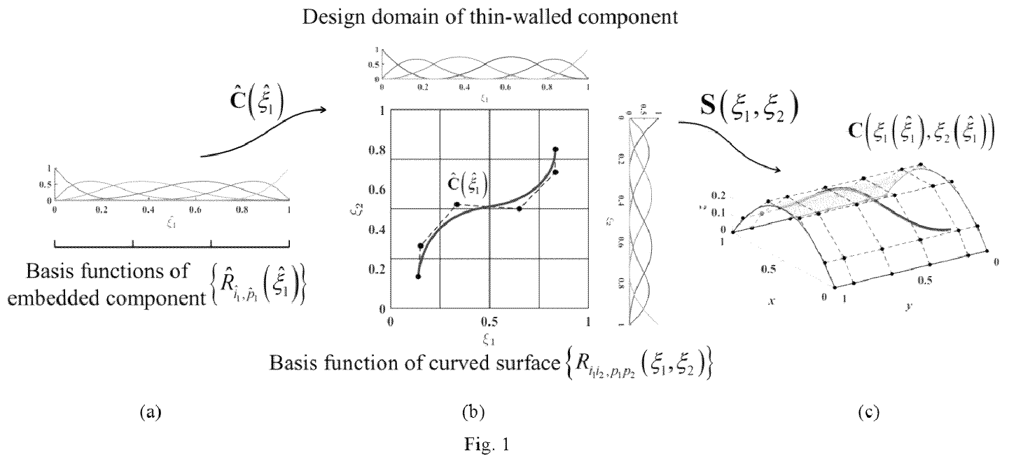

An adaptive geometric modeling method oriented to integration of modeling, analysis and optimization for assembled thin-walled component structures provided by one embodiment of the present invention comprises the following steps:
Step 100: using a multi-level NURBS-based free-form deformation (MNFFD) technique to realize accurate geometric modeling of an assembled thin-walled component structure, which comprises the following sub-steps:
Step 101: using a NURBS-based free-form deformation (NFFD) technique to establish implicit characterization relationships of a complex thin-walled structural model. First, embedding a NURBS curve into a parameter space of a NURBS curved surface, i.e., mapping from a 2D parameter space R² (ξ₁, ξ₂) to a 3D physical space R³ (x, y, z); a mapping relationship H^{c} of such a 2D-NFFD based modeling method is defined as follows:

$${H}^{c} : {ℝ}^{2} ( \hat{C} ( {\hat{ξ}}_{1} ) ) \to {ℝ}^{3} ( C ( {ξ}_{1} ( {\hat{ξ}}_{1} ) , {ξ}_{2} ( {\hat{ξ}}_{1} ) ) ) ,$$

where \hat{ξ}₁ is a parameter coordinate of an embedded curve Ĉ, ξ₁ and ξ₂ are parameter coordinates of the embedded curve in the NURBS curved surface, and C is a mapping curve. This relationship is achieved by mapping from the parameter space of the NURBS curved surface to the physical space in the following equation. An expression of the embedded curve shown in FIG. 1(b) is:

$$\hat{C} ( {\hat{ξ}}_{1} ) = [ \begin{matrix}{ξ}_{1} ( {\hat{ξ}}_{1} ) \\ {ξ}_{2} ( {\hat{ξ}}_{1} )\end{matrix} ] = {\sum }_{{\hat{l}}_{1} = 1}^{{\hat{n}}_{1}} {R}_{{\hat{l}}_{1} , {\hat{p}}_{1}} ( {\hat{ξ}}_{1} ) {\hat{P}}_{{\hat{l}}_{1}} ,$$

where R_{\hat{ι}}_{₁}_{,\hat{p}}_{₁} represents a NURBS basis function of the embedded curve; \hat{P}ᵢ_{₁}∈ [symbol] is a control point corresponding to the basis function; and \hat{ι}₁=1, 2, . . . , \hat{n}₁ represents a serial number of the control point. A definition of the mapping curve in the NURBS curved surface can be obtained, which is:

$${C}^{m} ( {\hat{ξ}}_{1} ) = {[ x ( {\hat{ξ}}_{1} ) y ( {\hat{ξ}}_{1} ) z ( {\hat{ξ}}_{1} ) ]}^{T} = {\sum }_{{l}_{1} = 1}^{{n}_{1}} {\sum }_{{l}_{2} = 1}^{{n}_{2}} {R}_{{i}_{1} , {i}_{2} , {p}_{1} {p}_{2}} ( {ξ}_{1} ( {\hat{ξ}}_{1} ) , {ξ}_{2} ( {\hat{ξ}}_{1} ) ) {P}_{{i}_{1} , {i}_{2}} ,$$

where Rᵢ_{₁}ᵢ_{₂}_{,p}_{₁}ₚ_{₂} represents a basis function of the NURBS curved surface i₁=1 [symbol] 2 [symbol] . . . [symbol] n₂ represents a serial number of a control point in the direction of ξ₁; i₂=1 [symbol] 2 [symbol] . . . [symbol] n₂ represents a serial number of a control point in the direction of ξ₂; and Pᵢ_{₁}_{,i}_{₂} is a control point corresponding to the basis function of the NURBS curved surface.

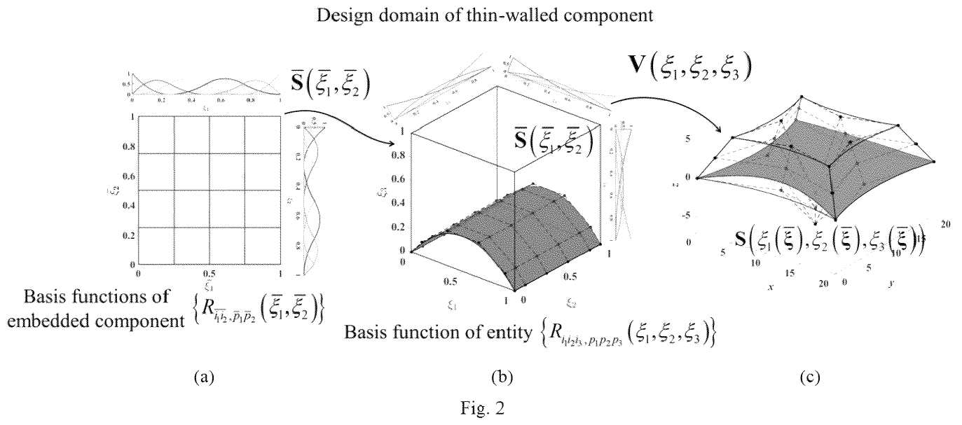

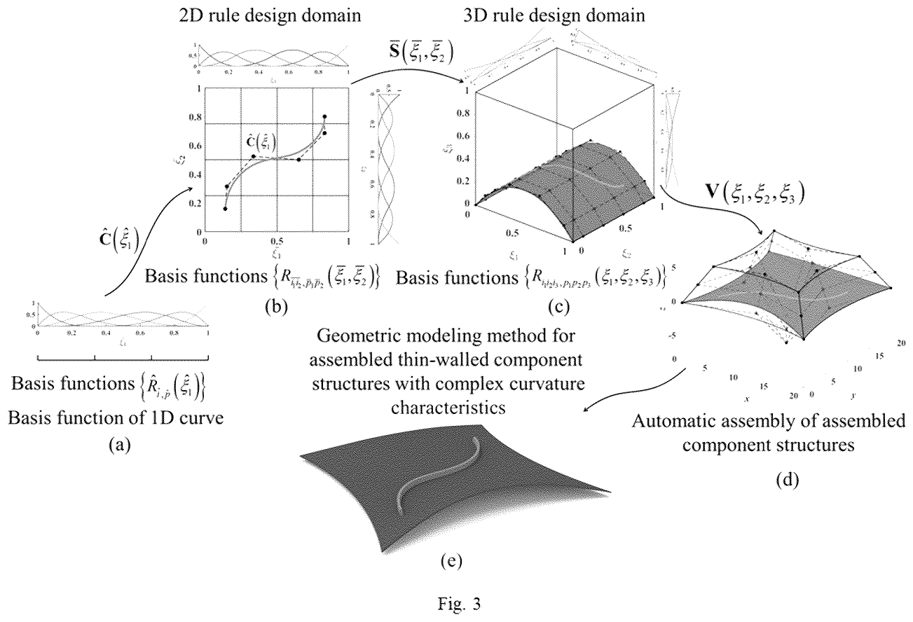

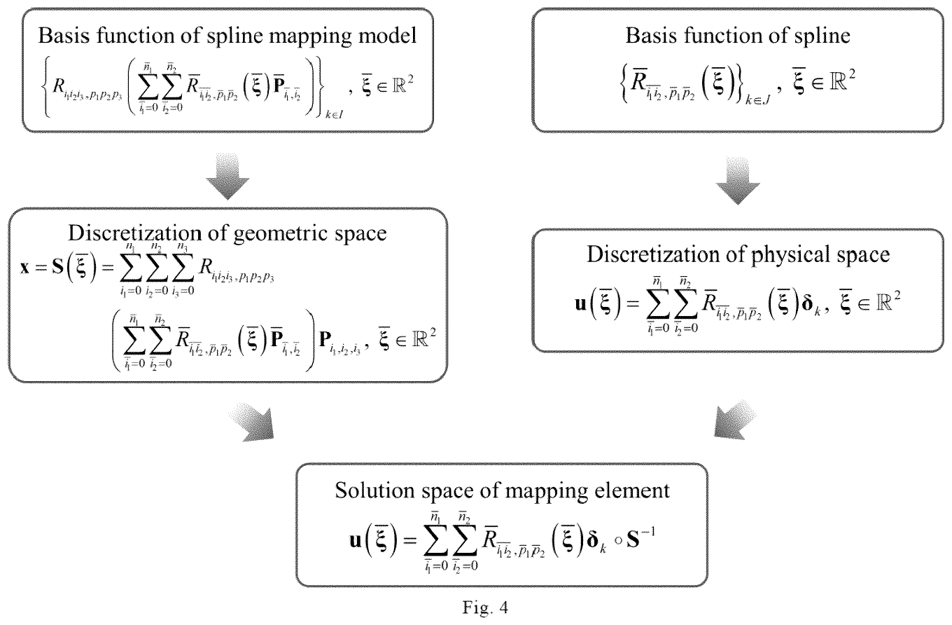

The definition ensures that any point of the curve is in the curved surface, as shown in FIG. 1(c). A 2D-NFFD based solid is a composite form of a NURBS solid, and a mapping function thereof is a composite form of the NURBS basis function. In addition, embedding a NURBS curved surface into a parameter space of the NURBS solid, i.e., mapping from a 3D parameter space R³ (ξ₁, ξ₂, ξ₃) to a 3D physical space R³ (x, y, z). A basic principle of such a 3D-NFFD based modeling method is the same as that of the 2D-NFFD based modeling method, and a mapping relationship H^{s} thereof is defined as follows:

$${H}^{s} : {ℝ}^{3} ( \tilde{S} ( {\tilde{ξ}}_{1} , {\tilde{ξ}}_{2} ) ) \to {ℝ}^{3} ( S ( {ξ}_{1} ( \tilde{ξ} ) , {ξ}_{2} ( \tilde{ξ} ) , {ξ}_{3} ( \tilde{ξ} ) ) ) ,$$

where ξ̅₁ and ξ̅₂ are parameter coordinates of an embedded curved surface S̅; ξ₁, ξ₂ and ξ₃ are parameter coordinates of the embedded curved surface in the NURBS solid; and S is a mapping curved surface. The curved surface is embedded into the parameter space of the NURBS solid. As shown in FIG. 2, a solid modeling principle based on 3D NFFD is introduced by taking the curved surface as an example. A definition of the embedded curved surface is:

$$\overline{S} ( {\overline{ξ}}_{1} , {\overline{ξ}}_{2} ) = {[ {ξ}_{1} , {ξ}_{2} , {ξ}_{3} ]}^{T} = {\sum }_{{\overline{l}}_{1} = 1}^{{\overline{n}}_{1}} {\sum }_{{\overline{l}}_{2} = 1}^{{\overline{n}}_{2}} {\overline{R}}_{{\overline{l}}_{1} , {\overline{l}}_{2} , {\overline{p}}_{1} {\overline{p}}_{2}} ( {\overline{ξ}}_{1} , {\overline{ξ}}_{2} ) {\overline{P}}_{{\overline{l}}_{1} , {\overline{l}}_{2}} ,$$

where R̅_{ι̅}_{₁}_{ι̅}_{₂}_{,p̅}_{₁}_{p̅}_{₂} represents a NURBS basis function of the embedded curved surface; P̅_{ι̅}_{₁}_{ι̅}_{₂}∈ [symbol] is a control point corresponding to the basis function; i₁=1 [symbol] 2 [symbol] . . . [symbol] n₁ represents a serial number of a control point in the direction of ξ̅₁; and i₂=1 [symbol] 2 [symbol] . . . [symbol] n₂ represents a serial number of a control point in the direction of ξ̅₂. The embedded curved surface is embedded into the parameter space of the NURBS solid and mapped from the 3D parameter space to the 3D physical space by the basis function of the NURBS solid. A definition of the mapping curved surface is:

$$\overline{S} ( \overline{ξ} ) = {[ x ( \overline{ξ} ) , y ( \overline{ξ} ) , z ( \overline{ξ} ) ]}^{T} = {\sum }_{{i}_{1} = 1}^{{n}_{1}} {\sum }_{{i}_{2} = 1}^{{n}_{2}} {\sum }_{{i}_{3} = 1}^{{n}_{3}} {R}_{{i}_{1} {i}_{2} {i}_{3} , {p}_{1} {p}_{2} {p}_{3}} ( {\sum }_{{\overline{l}}_{1} = 1}^{{\overline{n}}_{1}} {\sum }_{{\overline{l}}_{2} = 1}^{{\overline{n}}_{2}} {\overline{R}}_{{\overline{l}}_{1} {\overline{l}}_{2} , {\overline{p}}_{1} {\overline{p}}_{2}} ( \overline{ξ} ) {\overline{P}}_{{\overline{l}}_{1} , {\overline{l}}_{2}} ) {P}_{{i}_{1} , {i}_{2} , {i}_{3}} ,$$

where R̅_{ι̅}_{₁}_{ι̅}_{₂}_{,p̅}_{₁}_{p̅}_{₂} represents the basis function of the embedded curved surface; Rᵢ_{₁}ᵢ_{₂}ᵢ_{₃}_{,p}_{₁}ₚ_{₂}ₚ_{₃} represents the basis function of the NURBS solid; ι̅₁=1 [symbol] 2 [symbol] . . . , n̅₁ and ι̅₂=1 [symbol] 2 [symbol] . . . [symbol] n̅₂ represent serial numbers of control points of the embedded curved surface in the directions of two parameters; i₁=1 [symbol] 2 [symbol] . . . [symbol] n₁, i₂=1 [symbol] 2 [symbol] . . . [symbol] n₂ and i₃=1 [symbol] 2 [symbol] . . . [symbol] n₃ represent serial numbers of control points of the NURBS solid in the directions of three parameters; P̅_{ι̅}_{₁}_{,ι̅}_{₂} is a control point corresponding to the basis function of the embedded curved surface; and Pᵢ_{₁}_{,i}_{₂}_{,i}_{₃} is a control point corresponding to the basis function of the NURBS solid.
Step 102: allowing multi-level and composite mapping of a structure and proposing an MNFFD method according to the two mapping relationships mentioned in step 101 on the basis of an original NFFD method of single-level mapping to establish the implicit characterization relationships of an assembled thin-walled component structural model based on MNFFD. Both 2D-NFFD and 3D-NFFD based solids adopts only single mapping; on this basis, the two kinds of mapping (H^{c}&H^{s}) are combined, and a multi-level NFFD method is established. A quadratic mapping H^{m} is defined as follows:

$${H}^{m} : {ℝ}^{2} ( \hat{C} ( {\hat{ξ}}_{1} ) ) \to {ℝ}^{3} ( \overline{C} ( {\overline{ξ}}_{1} ( {\hat{ξ}}_{1} ) , {\overline{ξ}}_{2} ( {\hat{ξ}}_{1} ) ) ) \to {ℝ}^{3} ( C ( {ξ}_{1} ( {\hat{ξ}}_{1} ) , {ξ}_{2} ( {\hat{ξ}}_{1} ) , {ξ}_{3} ( {\hat{ξ}}_{1} ) ) ) ,$$

where \hat{ξ}₁ is the parameter coordinate of the embedded curved surface Ĉ; ξ̅₁ and ξ̅₂ are the parameter coordinates of the embedded curve in the curved surface; ξ₁, ξ₂ and ξ₃ are parameter coordinates of the embedded curve in the NURBS solid; Ĉ is the embedded curve, C̅ is the mapping curve in the physical space of the embedded curved surface S̅, and C is a mutual mapping curve in the mapping curved surface S. A definition of the mutual mapping curve is:

$${C}^{bm} ( {\hat{ξ}}_{1} ) = {[ x ( \overline{ξ} ) , y ( \overline{ξ} ) , z ( \overline{ξ} ) ]}^{T} = {\sum }_{{i}_{1} = 1}^{{n}_{1}} {\sum }_{{i}_{2} = 1}^{{n}_{2}} {\sum }_{{i}_{3} = 1}^{{n}_{3}} {R}_{{i}_{1} {i}_{2} {i}_{3} , {p}_{1} {p}_{2} {p}_{3}} ( {\sum }_{{\overline{l}}_{1} = 1}^{{\overline{n}}_{1}} {\sum }_{{\overline{l}}_{2} = 1}^{{\overline{n}}_{2}} {\overline{R}}_{{\overline{l}}_{1} {\overline{l}}_{2} , {\overline{p}}_{1} {\overline{p}}_{2}} ( {\sum }_{{\hat{l}}_{1} = 1}^{{\hat{n}}_{1}} {R}_{{\hat{l}}_{1} , {\hat{p}}_{1}} ( {\hat{ξ}}_{1} ) {\hat{P}}_{{\hat{l}}_{1}} ) {\overline{P}}_{{\overline{l}}_{1} , {\overline{l}}_{2}} ) {P}_{{i}_{1} , {i}_{2} , {i}_{3}} ,$$

where R_{ι}_{₁}_{,\hat{p}}_{₁} represents the basis function of the embedded curve, and R̅_{ι̅}_{₁}_{ι̅}_{₂}_{,p̅}_{₁}_{p̅}_{₂} represents the basis function of the embedded curved surface; Rᵢ_{₁}ᵢ_{₂}ᵢ_{₃}_{,p}_{₁}ₚ_{₂}ₚ_{₃} represents the basis function of the NURBS solid; \hat{ι}₁=1 [symbol] 2 [symbol] . . . [symbol] \hat{n}₁ represents a serial number of a control point of the embedded curve; ι̅₁=1 [symbol] 2 [symbol] . . . [symbol] n̅₁ and ι̅₂=1 [symbol] 2 [symbol] . . . [symbol] n̅₂ represent serial numbers of control points of the embedded curved surface in the directions of two parameters; i₁=1 [symbol] 2 [symbol] . . . [symbol] n₁, i₂=1 [symbol] 2 [symbol] . . . [symbol] n₂ and i₃=1 [symbol] 2 [symbol] . . . [symbol] n₃ represent serial numbers of control points of the NURBS solid in the directions of three parameters; \hat{P}_{\hat{ι}}_{₁} is a control point corresponding to the basis function of the embedded curve; P̅_{ι̅}_{₁}_{,ι̅}_{₂} is a control point corresponding to the basis function of the embedded curved surface; and Pᵢ_{₁}_{,i}_{₂}_{,i}_{₃} is a control point corresponding to the basis function of the NURBS solid. As an example, FIG. 3 shows a stiffened structure constructed based on the MNFFD method, and the stiffened structure shown in FIG. 3(e) is composed of a mutual mapping curve (stiffener) and a mapping curved surface (skin).
Step 200: establishing a modeling-analysis unified model suitable for isogeometric analysis of the assembled thin-walled component structure based on the MNFFD method, which comprises the following sub-steps:
Step 201: deriving theoretical formulas of a 6-degree-of-freedom degenerated shell element and a 6-degree-of-freedom degenerated beam element based on the MNFFD mapping model according to an isogeometric paradigm. For a mapping degenerated shell element, a geometric model in the physical space is implicitly defined by the mapping surface. At this time, a classical formula of an isogeometric shell element is no longer applicable, and therefore a new mapping element is established in the present embodiment to be applied to the isogeometric analysis of such models. The idea of the mapping element is to use the same parameter space, an approximate space of a solution is discretized by a basis function of an embedded solid, and the geometric model is discretized by a basis function of a mapping solid. In this case, the kinematic theory of the shell element will not be changed, but unlike a traditional formula of the shell element based on NURBS, the formula of the shell element based on the MNFFD method requires the re-derivation of all physical quantities related to geometric parameters based on the mapping solid. FIG. 4 shows a process of solving a formula of a mapping shell element, wherein different shape functions are used for geometric parameterization and solution approximation, respectively.

A geometric model of the mapping shell element is based on the mapping curved surface in 3D-NFFD based modeling method, and a principle thereof is that the embedded surface is embedded into the parameter space of the NURBS solid, and the mapping curved surface is finally obtained by a mapping transformation relationship of the NURBS solid. A definition of the embedded curved surface is:

$$\overline{S} ( {\overline{ξ}}_{1} , {\overline{ξ}}_{2} ) = {\sum }_{{\overline{l}}_{1} {\overline{l}}_{2}} {\overline{R}}_{{\overline{l}}_{1} {\overline{l}}_{2}} ( {\overline{ξ}}_{1} , {\overline{ξ}}_{2} ) {\overline{P}}_{{\overline{l}}_{1} , {\overline{l}}_{2}} .$$

In the formula of the mapping degenerated shell element, the embedded curved surface is used for discrete solution approximation. The embedded curved surface will be mapped to the physical space of the NURBS solid. According to the 3D-NFFD mapping transformation relationship, the mapping curved surface is defined as:

$$\overline{S} ( {\overline{ξ}}_{1} , {\overline{ξ}}_{2} ) = V ( \overline{S} ( {\overline{ξ}}_{1} , {\overline{ξ}}_{2} ) ) = {\sum }_{{i}_{1} {i}_{2} {i}_{3}} {R}_{{i}_{1} {i}_{2} {i}_{3}} ( {\overline{R}}_{{\overline{l}}_{1} {\overline{l}}_{2}} ( {\overline{ξ}}_{1} , {\overline{ξ}}_{2} ) {\overline{P}}_{{\overline{l}}_{1} , {\overline{l}}_{2}} ) {P}_{{i}_{1} , {i}_{2} , {i}_{3}} .$$

A coordinate vector of the mapping shell element is:

$$x ( {\overline{ξ}}_{1} , {\overline{ξ}}_{2} , ζ ) = \{ \begin{matrix}x ( {\overline{ξ}}_{1} , {\overline{ξ}}_{2} , ζ ) \\ y ( {\overline{ξ}}_{1} , {\overline{ξ}}_{2} , ζ ) \\ z ( {\overline{ξ}}_{1} , {\overline{ξ}}_{2} , ζ )\end{matrix} \} = \sum {N}_{i} ( {\overline{ξ}}_{1} , {\overline{ξ}}_{2} ) \{ \begin{matrix}{x}_{i} \\ {y}_{i} \\ {z}_{i}\end{matrix} \} + \frac{ζ t}{2} {\overline{v}}_{3} ( {\overline{ξ}}_{1} , {\overline{ξ}}_{2} ) ,$$

where v̅₃ is a normal vector of the mapping curved surface in the physical space of the NURBS solid; Nᵢ represents the basis function of the NURBS curved surface; ζ represents a parameter coordinate in a thickness direction of a shell; t represents a thickness of the shell; and three direction vectors {v̅₁, v̅₂, v̅₃} in local coordinates of the mapping curved surface are defined by derivatives of the mapping curved surface,

$${\overline{v}}_{3} = \frac{\frac{\partial s ( {\overline{ξ}}_{1} , {\overline{ξ}}_{2} )}{\partial {\overline{ξ}}_{1}} \times \frac{\partial s ( {\overline{ξ}}_{1} , {\overline{ξ}}_{2} )}{\partial {\overline{ξ}}_{2}}}{\vert \frac{\partial s ( {\overline{ξ}}_{1} , {\overline{ξ}}_{2} )}{\partial {\overline{ξ}}_{1}} \times \frac{\partial s ( {\overline{ξ}}_{1} , {\overline{ξ}}_{2} )}{\partial {\overline{ξ}}_{2}} \vert} , {\overline{v}}_{1} = \frac{\frac{\partial s ( {\overline{ξ}}_{1} , {\overline{ξ}}_{2} )}{\partial {\overline{ξ}}_{1}}}{\vert \frac{\partial s ( {\overline{ξ}}_{1} , {\overline{ξ}}_{2} )}{\partial {\overline{ξ}}_{1}} \vert} , {\overline{v}}_{2} = {\overline{v}}_{3} \times {\overline{v}}_{1} .$$

A displacement vector is defined by a translational displacement {uᵢ, vᵢ, wᵢ}^{T} and a rotation angle {αₓᵢ, α_{yi}, α_{zi}}^{T} of the control point, each control point contains 6 control variables δᵢ={uᵢ, vᵢ, wᵢ, αₓᵢ, α_{yi}, α_{zi}}^{T} which are all in a global coordinate system (x−y−z),

$$u ( {ξ}_{1} , {ξ}_{2} , ζ ) = \{ \begin{matrix}u ( {ξ}_{1} , {ξ}_{2} , ζ ) \\ v ( {ξ}_{1} , {ξ}_{2} , ζ ) \\ w ( {ξ}_{1} , {ξ}_{2} , ζ )\end{matrix} \} = \sum {R}_{i} ( {ξ}_{1} , {ξ}_{2} ) ( {u}_{i} + {u}_{α i} ( ζ ) ) ,$$

where

$${u}_{i} = \{ \begin{matrix}{u}_{i} \\ {v}_{i} \\ {w}_{i}\end{matrix} \} , {u}_{α i} ( ζ ) = \frac{ζ {t}_{i}}{2} {Φ}_{i} {α}_{i} = [ \begin{matrix}0 & {n}_{3 i} & - {m}_{3 i} \\ - {n}_{3 i} & 0 & {l}_{3 i} \\ {m}_{3 i} & - {l}_{3 i} & 0\end{matrix} ] \{ \begin{matrix}{α}_{xi} \\ {α}_{yi} \\ {α}_{zi}\end{matrix} \}$$

For a mapping degenerated beam element, mapping curves under an MNFFD framework includes single mapping curves and mutual mapping curves which can be used for representing trimming curves and stiffeners in the assembled thin-walled component structure. A 3D beam element adopting explicit spline curves is improved into a NURBS-based stiffener element, and the original explicit curves are replaced by the mapping curves, thus to derive a mapping stiffener element from the classical NURBS-based stiffener element.

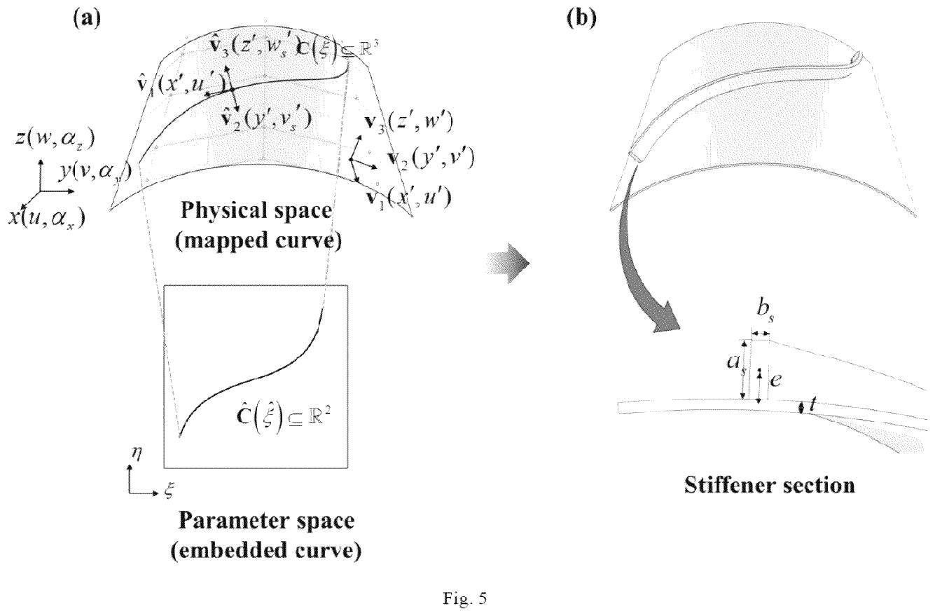

A single mapping stiffener element is described below, and a definition of a single mapping curve is shown in step 101. For the single mapping stiffener element, direction vectors in a local coordinate system of a mapping curve are the most important, which directly determine the property of a cross-section of a stiffener. FIG. 5 shows local direction vectors of a mapping stiffener and a skin curved surface. In general, a height direction of the stiffener is consistent with a normal direction of the skin, which is defined as follows:

$$\begin{matrix}{\hat{v}}_{3}^{s} ( \hat{ξ} ) = {\{ {\hat{l}}_{3} , {\hat{m}}_{3} , {\hat{n}}_{3} \}}^{T} \\ = {\hat{v}}_{3}^{s} ( {ξ}_{1} ( {\hat{ξ}}_{1} ) , {ξ}_{2} ( {\hat{ξ}}_{1} ) ) \\ = \frac{\frac{\partial }{\partial {ξ}_{1}} S ( {ξ}_{1} ( {\hat{ξ}}_{1} ) , {ξ}_{2} ( {\hat{ξ}}_{1} ) ) \times \frac{\partial }{\partial {ξ}_{2}} S ( {ξ}_{1} ( {\hat{ξ}}_{1} ) , {ξ}_{2} ( {\hat{ξ}}_{1} ) )}{‖ \frac{\partial }{\partial {ξ}_{1}} S ( {ξ}_{1} ( {\hat{ξ}}_{1} ) , {ξ}_{2} ( {\hat{ξ}}_{1} ) ) \times \frac{\partial }{\partial {ξ}_{2}} S ( {ξ}_{1} ( {\hat{ξ}}_{1} ) , {ξ}_{2} ( {\hat{ξ}}_{1} ) ) ‖} ,\end{matrix}$$

where \hat{v}₃^{s} represents a direction vector in the height direction of the stiffener; and {\hat{l}₃, \hat{m}₃, \hat{n}₃} represents three direction components in the height direction of the stiffener, respectively. A principal direction of the stiffener is a derivative of the mapping curve with respect to a parameter coordinate \hat{ξ},

$${\hat{ν}}_{1}^{s} ( {\hat{ξ}}_{1} ) = {\{ {\hat{l}}_{1} , {\hat{m}}_{1} , {\hat{n}}_{1} \}}^{T} = \frac{\frac{\partial {C}^{m} ( {\hat{ξ}}_{1} )}{\partial {\hat{ξ}}_{1}}}{‖ \frac{\partial {C}^{m} ( {\hat{ξ}}_{1} )}{\partial {\hat{ξ}}_{1}} ‖} , \frac{\partial {C}^{m} ( {\hat{ξ}}_{1} )}{\partial {\hat{ξ}}_{1}} = \sum \frac{\partial {N}_{{i}_{1} {i}_{2}}^{m} ( {\hat{ξ}}_{1} )}{\partial {\hat{ξ}}_{1}} {P}_{ij} ,$$

where \hat{v}₁^{s} represents a direction vector in the principal direction of the stiffener; {\hat{l}₁, \hat{m}₁, \hat{n}₁} represents direction components in the principal direction of the stiffener, respectively; Pᵢⱼ represents a control point of the skin curved surface; Nᵢ_{₁}ᵢ_{₂}^{m}(\hat{ξ}₁) is a multi-level NURBS basis function of the mapping curve, and Nᵢ_{₁}ᵢ_{₂}^{m}(\hat{ξ}₁) writes,

$${N}_{{i}_{1} {i}_{2}}^{m} ( \overline{ξ} ) = {R}_{{i}_{1} {i}_{2} , {p}_{1} {p}_{2}} ( {\sum }_{{\hat{ι}}_{1} = I}^{{\hat{n}}_{1}} {\hat{R}}_{{\hat{ι}}_{1} , {\hat{p}}_{1}} ( {\hat{ξ}}_{1} ) {\hat{P}}_{{\hat{ι}}_{1}} ) .$$

A derivative thereof with respect to the parameter coordinate \hat{ξ}₁ is

$$\begin{matrix}\frac{\partial {N}_{{i}_{1} {i}_{2}}^{m} ( \hat{ξ} )}{\partial \hat{ξ}} = \frac{\partial {R}_{{i}_{1} {i}_{2} , {p}_{1} {p}_{2}} ( {\sum }_{{\hat{i}}_{1} = 0}^{{\hat{n}}_{1}} {\hat{R}}_{{\hat{i}}_{1} , {\hat{p}}_{1}} ( \hat{ξ} ) {\hat{P}}_{{\hat{i}}_{1}} )}{\partial \hat{ξ}} \\ = \frac{\partial {R}_{{i}_{1} {i}_{2} , {p}_{1} {p}_{2}}}{\partial {ξ}_{1}} \frac{\partial {ξ}_{1}}{\partial \hat{ξ}} + \frac{\partial {R}_{{i}_{1} {i}_{2} , {p}_{1} {p}_{2}}}{\partial {ξ}_{2}} \frac{\partial {ξ}_{2}}{\partial \hat{ξ}} \\ = \frac{\partial {R}_{{i}_{1} {i}_{2} , {p}_{1} {p}_{2}}}{\partial {ξ}_{1}} {\sum }_{\overline{i} = 1}^{\overline{n}} \frac{\partial {\hat{R}}_{{\hat{i}}_{1} , {\hat{p}}_{1}} ( \hat{ξ} )}{\partial \hat{ξ}} {\hat{P}}_{{\hat{i}}_{1}} + \frac{\partial {R}_{{i}_{1} {i}_{2} , {p}_{1} {p}_{2}}}{\partial {ξ}_{2}} {\sum }_{\overline{i} = 1}^{\overline{n}} \frac{\partial {\hat{R}}_{{\hat{i}}_{1} , {\hat{p}}_{1}} ( \hat{ξ} )}{\partial \hat{ξ}} {\hat{P}}_{{\hat{i}}_{1}}\end{matrix}$$

According to the previous formulas, a direction vector in a width direction of a stiffener element is:

$${\hat{v}}_{2}^{s} ( {\hat{ξ}}_{1} ) = {\{ {\hat{l}}_{2} , {\hat{m}}_{2} , {\hat{n}}_{2} \}}^{T} = \frac{{\hat{v}}_{3}^{s} ( {\hat{ξ}}_{1} ) \times {\hat{v}}_{1}^{s} ( {\hat{ξ}}_{1} )}{‖ {\hat{v}}_{3}^{s} ( {\hat{ξ}}_{1} ) \times {\hat{v}}_{1}^{s} ( {\hat{ξ}}_{1} ) ‖} .$$

A coordinate vector at any point (\hat{ξ}₁, ηₛ, ζₛ) on the mapping stiffener element is as follows:

$${x}_{s} = \{ \begin{matrix}{x}_{s} \\ {y}_{s} \\ {z}_{s}\end{matrix} \} = \sum {N}_{{i}_{1} {i}_{2}}^{m} ( {\hat{ξ}}_{1} ) \{ \begin{matrix}{x}_{i} \\ {y}_{i} \\ {z}_{i}\end{matrix} \} + ( \frac{{ζ}_{s}}{2} {a}_{s} + e ) {\hat{v}}_{3}^{s} ( {\hat{ξ}}_{1} ) + \frac{{η}_{s}}{2} {b}_{s} {\hat{v}}_{2}^{s} ( {\hat{ξ}}_{1} ) ,$$

where {xᵢ, yᵢ, zᵢ} is a global coordinate system of a curved surface; e represents an offset distance from a central line of the stiffener to a middle surface of the shell; ζₛ represents a parameter coordinate in the height direction of the stiffener; aₛ represents a height of the stiffener; ηₛ represents a parameter coordinate in a width direction of the stiffener; bₛ represents a width of the stiffener; and \hat{v}₂^{s} represents a direction vector in the width direction of the stiffener.

A unique feature of the mapping stiffener element is that coupling of a stiffener curve with the skin curved surface can be achieved naturally without the need of projecting the curve into the parameter space of the curved surface or adding a transformation matrix. A principle of natural coupling is that deformation of the curved surface can be automatically transferred to the mapping curve via 2D-NFFD, and the displacement vector of a single mapping 6-degree-of-freedom degenerated stiffener element is defined by control variables of the shell and a normal direction of the shell,

$${u}_{s} = \{ \begin{matrix}{u}_{s} \\ {v}_{s} \\ {w}_{s}\end{matrix} \} = [ {T}_{v}^{s} ( \hat{ξ} ) ] \sum {N}_{{i}_{1} {i}_{2}}^{m} ( \hat{ξ} ) \{ \begin{matrix}{u}_{i} \\ {v}_{i} \\ {w}_{i}\end{matrix} \} + \sum {N}_{{i}_{1} {i}_{2}}^{m} ( \overline{ξ} ) ( \frac{{ζ}_{s} {a}_{s}}{2} + e ) [ \begin{matrix}0 & {n}_{3 i} & - {m}_{3 i} \\ - {n}_{3 i} & 0 & {l}_{3 i} \\ {m}_{3 i} & - {l}_{3 i} & 0\end{matrix} ] \{ \begin{matrix}{α}_{x i} \\ {α}_{y i} \\ {α}_{z i}\end{matrix} \} ,$$

where {uᵢ, vᵢ, wᵢ, αₓᵢ, α_{yi}, α_{zi}} are control variables of the shell, [l₃ᵢ, m₃ᵢ, n₃ᵢ] are direction components in the normal direction of the shell, Tᵥ(\hat{ξ}) is a coordinate transformation matrix which is used for eliminating a displacement of the cross-section of the stiffener in y direction, thus to solve the conflict between shell kinematics and beam kinematics.

A mutual mapping stiffener element is described below. The construction manner of the element is similar to that of the single mapping stiffener element, and the differences are that single mapping complex basis functions and derivatives are changed to double mapping complex basis functions and derivatives, and the form of representation of the local coordinate system is also changed from the original single mapping to mutual mapping. At the same time, a coupling relationship between the mutual mapping stiffener element and a mapping shell is still satisfied. The definition of the mutual mapping curve is shown in step 102.

A direction of the local coordinate system at any point on the mutual mapping curve is defined as follows:

$${\hat{v}}_{3}^{bs} ( {\hat{ξ}}_{1} ) = \frac{\frac{\partial \overline{s} ( \hat{c} ( {\hat{ξ}}_{1} ) )}{\partial {\overline{ξ}}_{1}} \times \frac{\partial s ( \hat{c} ( {\hat{ξ}}_{1} ) )}{\partial {\overline{ξ}}_{2}}}{\vert \frac{\partial s ( \hat{c} ( {\hat{ξ}}_{1} ) )}{\partial {\overline{ξ}}_{1}} \times \frac{\partial s ( \hat{c} ( {\hat{ξ}}_{1} ) )}{\partial {\overline{ξ}}_{2}} \vert} , \\ {\hat{v}}_{1}^{bs} ( {\hat{ξ}}_{1} ) = \frac{\frac{\partial {C}^{bs} ( {\hat{ξ}}_{1} )}{\partial {\overline{ξ}}_{1}}}{\vert \frac{\partial {C}^{bs} ( {\hat{ξ}}_{1} ) )}{\partial {\overline{ξ}}_{1}} \vert} , {\hat{v}}_{2}^{bs} ( {\hat{ξ}}_{1} ) = {\hat{v}}_{3}^{bs} ( {\hat{ξ}}_{1} ) \times {\hat{v}}_{1}^{bs} ( {\hat{ξ}}_{1} ) ,$$

where C^{bs} represents a mutual mapping stiffener curve; and {\hat{v}₁^{bs}, \hat{v}₂^{bs}, \hat{v}₃^{bs}} represents direction vectors in a local coordinate system of the mutual mapping stiffener curve. A derivation process of a coordinate vector is the same as that of the single mapping stiffener element, and the coordinate vector at any point of the mutual mapping stiffener element is represented as follows:

$${x}_{s} = \{ \begin{matrix}{x}_{s} \\ {y}_{s} \\ {z}_{s}\end{matrix} \} = \sum {N}_{{i}_{1} {i}_{2} {i}_{3}}^{bm} ( {\hat{ξ}}_{1} ) \{ \begin{matrix}{x}_{i} \\ {y}_{i} \\ {z}_{i}\end{matrix} \} + ( \frac{{ζ}_{s}}{2} {a}_{s} + e ) {v}_{3}^{b s} ( {\hat{ξ}}_{1} ) + \frac{{η}_{s}}{2} {b}_{s} {v}_{2}^{b s} ( {\hat{ξ}}_{1} ) .$$

A displacement vector of a double mapping 6-degree-of-freedom degenerated stiffener element is defined according to the control variables of the mapping shell and the normal direction of the mapping shell, and a displacement vector at any point of the double mapping stiffener element is represented as follows,

$${u}_{s} = \{ \begin{matrix}{u}_{s} \\ {v}_{s} \\ {w}_{s}\end{matrix} \} = [ {T}_{v}^{b s} ( {\hat{ξ}}_{1} ) ] \sum {N}_{{i}_{1} {i}_{2} {i}_{3}}^{b m} ( {\hat{ξ}}_{1} ) \{ \begin{matrix}{u}_{i} \\ {v}_{i} \\ {w}_{i}\end{matrix} \} + \sum {N}_{{i}_{1} {i}_{2} {i}_{3}}^{b m} ( {\hat{ξ}}_{1} ) ( \frac{{ζ}_{s} {a}_{s}}{2} + e ) [ \begin{matrix}0 & {\overline{n}}_{3 i} & - {\overline{m}}_{3 i} \\ - {\overline{n}}_{3 i} & 0 & {\overline{l}}_{3 i} \\ {\overline{m}}_{3 i} & - {\overline{l}}_{3 i} & 0\end{matrix} ] \{ \begin{matrix}{α}_{x i} \\ {α}_{y i} \\ {α}_{z i}\end{matrix} \} .$$

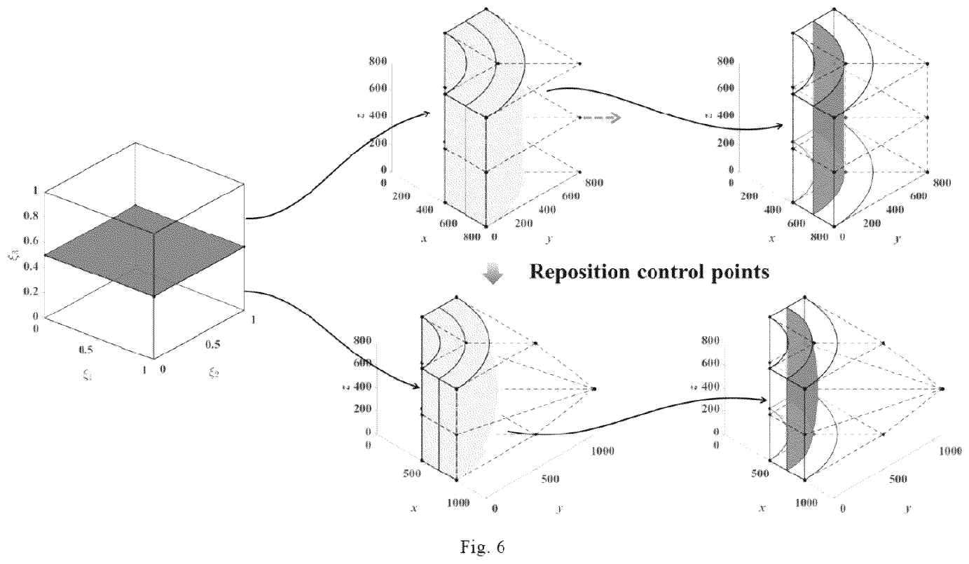

Step 202: establishing coupling of NURBS curved surface patches by a domain decomposition method in isogeometric analysis based on MNFFD to realize propagation of solutions between curved surfaces or mapping curved surfaces. In the present invention, a Lagrange multiplier method is used to complete connection between thin-walled components. The Lagrange multiplier method ensures that a constraint relationship at an interface is satisfied by applying a complementary field. The method is also called a mortar method in the condition that a mesh is inconsistent. According to the mortar method, it is not necessary to introduce stability parameters into a governing equation, and a Lagrange multiplier is directly introduced. In addition, control variables of a formula of a 6-degree-of-freedom shell element are located on the global coordinate system. Therefore, it is convenient to achieve uncoordinated connection of rotation variables, especially for structures with torsional deformation.
Step 300: establishing a modeling-analysis-design unified model suitable for collaborative design of a shape and a stiffened layout of the assembled thin-walled component structure based on the MNFFD method, which comprises the following sub-steps:
Step 301: as a mapping curved surface is an important thin-walled component in an MNFFD model, which can represent a skin, a ribbed plate or a stiffener, embedding the mapping curved surface into a 3D NURBS solid, changing a shape of a surrounding NURBS solid by moving control points thereof or modifying a weight value, and inheriting deformation by an object geometry of the mapping curved surface therein. A detailed process is shown as follows:
Modifying positions of control points: a shape of a control polygon of the NURBS solid can be easily and directly modified by repositioning the control points in a specified direction. Then a shape of the NURBS solid is changed, and deformation is transferred directly to the mapping curved surface through the mapping relationship between the NURBS solid and the NURBS curved surface. FIG. 6 shows a concrete example (In FIG. 6: after the position of a control point on the NURBS solid is modified, the shape of the mapping curved surface is changed synchronously with the deformation of the solid).

$${H}^{s} : {ℝ}^{3} ( \overline{S} ( {\overline{ξ}}_{1} , {\overline{ξ}}_{2} ) ) \to {ℝ}^{3} ( S ( {ξ}_{1} ( \overline{ξ} ) , {ξ}_{2} ( \overline{ξ} ) , {ξ}_{3} ( \overline{ξ} ) ) ) .$$

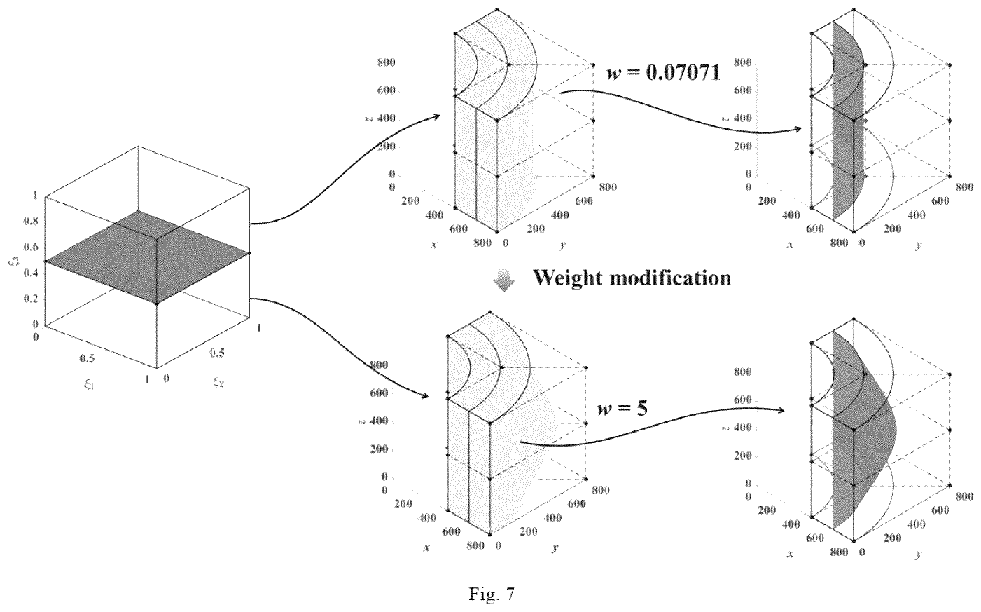

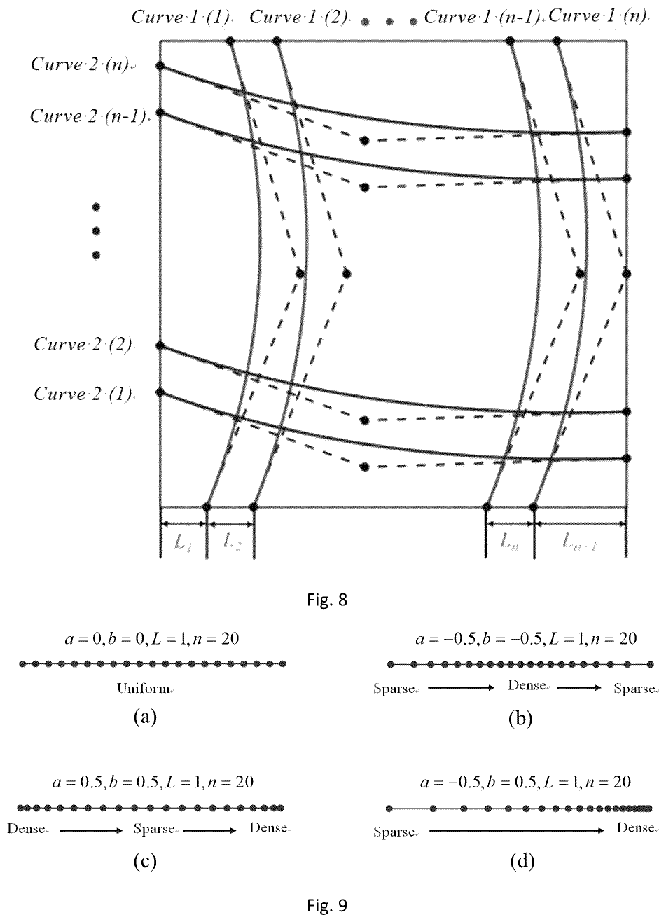

Modifying weights: in the present embodiment, weights are also used as design variables for shape optimization. By introducing weight coefficients, shape control becomes more flexible. The weights can be directly understood as the degree of attraction of the control point to the shape. When the weights are increased, the model will be deformed towards the control points. When the weights are decreased, the model will be deformed away from the control points. FIG. 7 shows a concrete example (In FIG. 7: after the weight of a control point on the NURBS solid is modified, the shape of the mapping curved surface is changed synchronously with the deformation of the solid).
Step 302: conducting parametric design of the stiffened layout in two parts: shapes of curves and spacing of stiffeners. The shapes of stiffener curves are defined by quadratic NURBS mapping curves, each curve is represented by the positions of at least three control points, and a group of similar NURBS curves are called a stiffener curve family, as shown in FIG. 8 (In FIG. 8: parameter definitions of a transverse stiffener curve family and a longitudinal stiffener curve family in a parameter space are shown, and each curve is represented by two control points on boundaries and one control point in the middle). In the present invention, stiffeners of a curve mesh are composed of two stiffener curve families, namely n curves 1 (in longitudinal direction) and n curves 2 (in transverse direction), a start control point and an end control point are located on the opposite boundaries of the parameter space, and shape control of the stiffener curve families is achieved by modifying the spacing among three groups of control points. At the same time, a geometric series function is defined to represent the spacing among the control points of each curve in the stiffener curve families, and the geometric series function is defined as:

$${L}_{i} = {{i}^{a} ( n - i + 1 )}^{b} \\ L = {\sum }_{i = 1}^{n} {L}_{i} ,$$

where a and b are design variables, L is the sum of the lengths of the spacing Lᵢ and also represents an edge length of the parameter space, and n−1 is the number of curves in the stiffener curve families. Different forms of non-uniform spacings can be obtained by the formula, as shown in FIG. 9 (In FIG. 9: the spacings of the stiffener curve families represented by the geometric series function with different parameters are shown). By modifying the geometric series function of one group of control points, the shape, the layout and the number of the stiffener curve families can be controlled simultaneously.

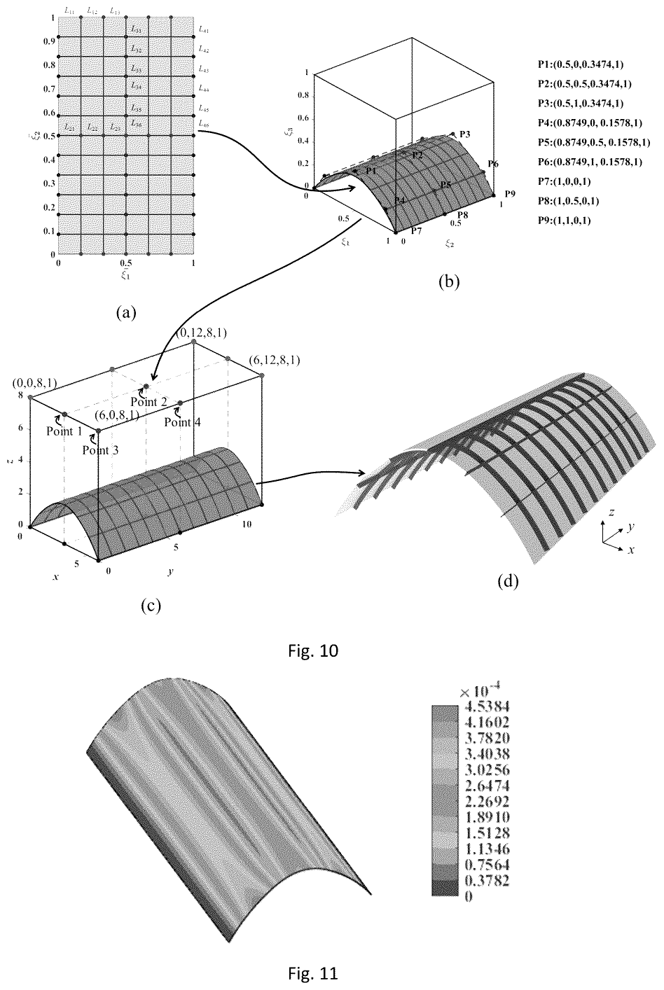

In the present embodiment, a roof model is selected as an example for shape optimization, and collaborative design of a shape and a stiffened layout of a shell is conducted based on an MNFFD geometric modeling method. FIG. 10 shows an initial model of a roof, wherein parameter settings of the stiffener curve families in the parameter space of the curved surface of the roof are shown in FIG. 10(a), and each stiffener curve family has three groups of control points. For the red stiffener curve family, the spacing among the control points is changed in the direction of ξ̅₁; for the blue stiffener curve family, the spacing among the control points is changed in the direction of ξ̅₂; and the spacing of each group of control points is defined by a geometric series function. Based on the symmetry of the model, the spacing of the control points of a quarter of the model is selected as a design variable. The spacing of the control points in the middle of the red stiffener curve family is controlled by defining one geometric series function, and initial variables thereof are a₁₁=0, b₁₁=0 and n₁=3. The spacing of the control points on the boundaries is controlled by defining another geometric series function, and initial variables are a₁₂=0, b₁₂=0 and n₁=3. The blue stiffener curve family adopts the same method to define two geometric series functions, which control the control points in the middle and the control points on the boundaries, respectively, and the initial variables are a₂₁=0, b₂₁=0, n₂=6 and a₂₂=0, b₂₂=0, n₂=6. In an optimization process, parameters of the cross-section of the stiffener are not changed: aₛ=0.15, bₛ=0.03 and e=aₛ/2. The shape of the shell is controlled by changing the positions and weights of the control points of the NURBS solid, and nine control points (four red control points and five blue control points) at the top of the NURBS solid are set as design variables. Based on the symmetry of the model, only a quarter of the model (four red control points) needs to be set as design variables, including z-direction coordinate and weight (s₁=8, w₁=1) of control point 1, z-direction coordinate and weight (s₂=8, w₂=1) of control point 2, a z-direction coordinate (s₃=8) of control point 3 and a z-direction coordinate (s₄=8) of control point 4, the coordinates and weights of the other five blue control points are changed synchronously based on symmetry. The thickness (t=0.05) of the shell is also used as a design variable. The optimization involves a total of 17 design variables, including 10 stiffened layout design variables, 6 shell shape optimization design variables and 1 shell size optimization design variable. An optimization formula is defined as follows:

$$find {x}_{s} = [ {a}_{11} , {b}_{11} , {a}_{12} , {b}_{12} , {n}_{1} , {a}_{21} , {b}_{21} , {a}_{22} , {b}_{22} , {n}_{2} , {s}_{1} , {s}_{2} , {s}_{3} , {s}_{4} , {w}_{1} , {w}_{2} , t ] \\ {min}_{{x}_{s}} f ( {x}_{s} ) \\ s . t . V ( {x}_{s} ) - {V}_{0} \leq 0 , min ( {L}_{i} ) - 2 {b}_{s} \geq 0 , - 1 \leq {a}_{11} , {b}_{11} , {a}_{12} , {b}_{12} , {a}_{21} , {b}_{21} , {a}_{22} , {b}_{22} \leq 1 , 2 \leq {n}_{1} \leq 5 \\ 4 \leq {n}_{2} \leq 11 \\ - 8 \leq {s}_{1} , {s}_{2} \leq 16 \\ 1 \leq {s}_{3} , {s}_{4} \leq 16 \\ 1 \leq {w}_{1} , {w}_{2} \leq 3$$

where f(•) is a structural strain energy, V(•) is a volume of the current model, V₀=5.236 is a volume of the initial model, min(Lᵢ) is the minimum value of all spacings, and the inequations can prevent the stiffeners from overlapping each other.

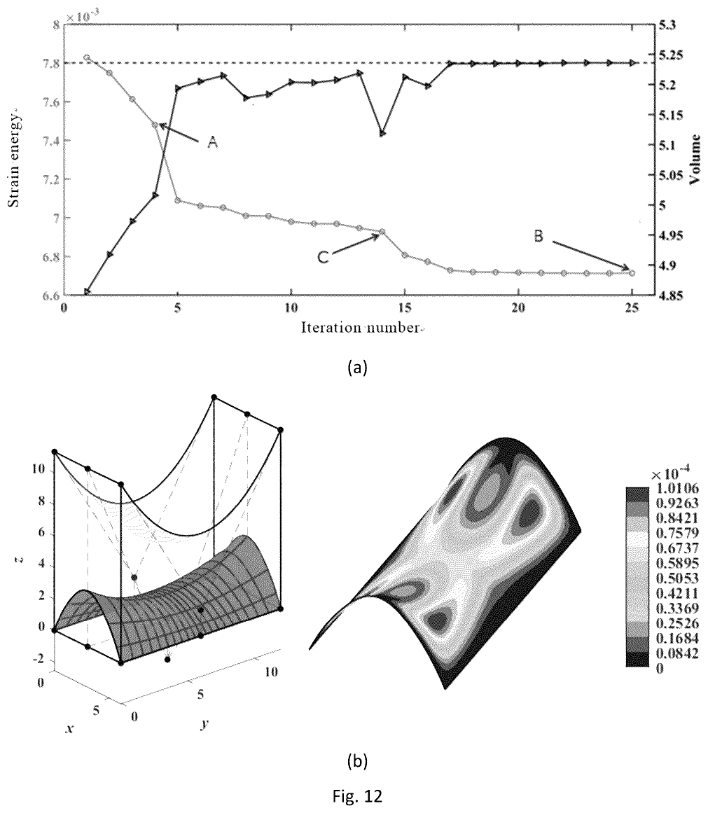

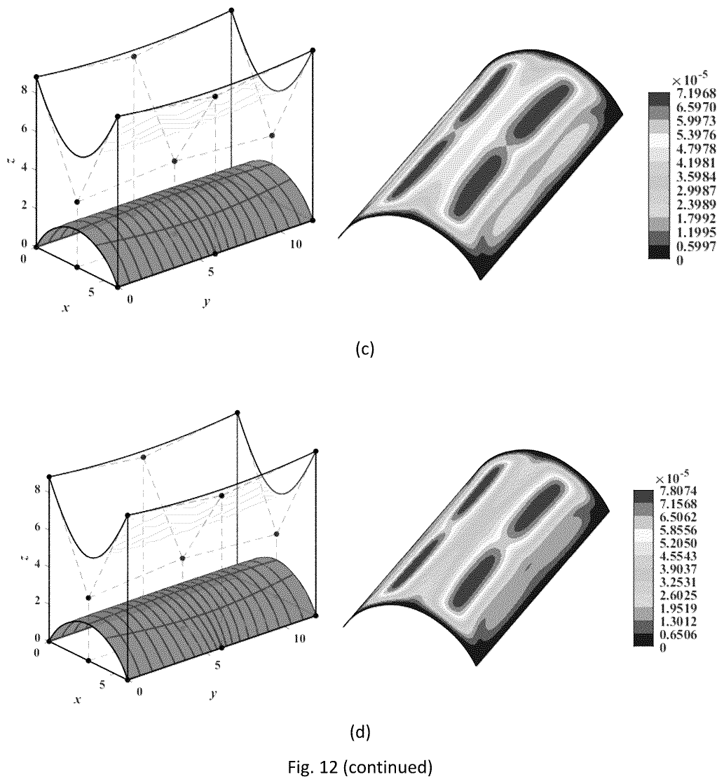

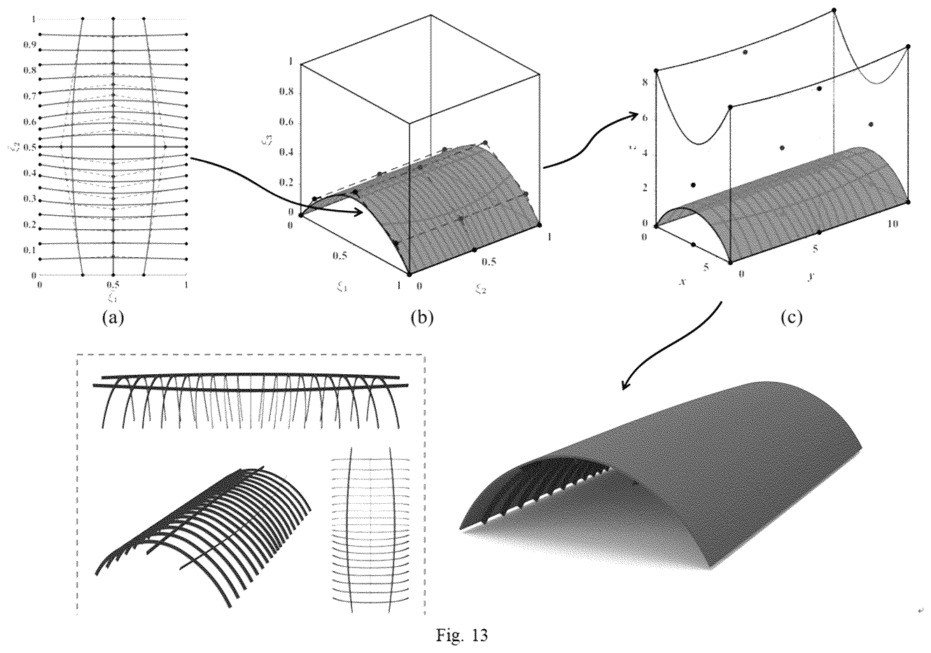

A load form of the structure is uniform vertical (snow) load, and collaborative optimization design of the shape and stiffened layout of the shell of a stiffened roof is conducted in boundary conditions that four boundaries are fixedly constrained. Matlab codes are used for modeling and analysis, and a multi-island genetic algorithm with a population size of 50, an island number of 5, and a genetic algebraic value of 25 based on Isight is used for optimization. In such boundary conditions, the displacement analysis results of the initial model are shown in FIG. 11, the strain energy of the initial model is 0.0124, and a displacement extremum is 2.9351e-4. FIG. 12 shows an iterative curve for optimization of the stiffened layout and shape of the shell, and the strain energy and volume converge stably. The optimal design variables are: a₁₁=0.188, b₁₁=0.403, a₁₂=0.719, b₁₂=0.210, n₁=2, a₂₁=0.740, b₂₁=0.162, a₂₂=−0.424, b₂₂=−1, n₂=10, s₁=4.419, s₂=5.679, s₃=7.830, s₄=13.309, w₁=1.203, w₂=1.770 and t=0.05. FIG. 13 shows a model of the stiffened roof after optimization. A shape of the stiffeners takes the form of a non-uniform curve, and interaction between the stiffener layout and the shape of the shell can be clearly observed during optimization iteration. The strain energy of an optimization model is 6.71e-3, which is 45.9% lower than that of the initial model. A displacement extremum of the optimization model is 7.1968e-5, which is 75% lower than that of the initial model. The overall stiffness of the model is effectively improved through collaborative optimization design at the same mass.

The present invention provides an MNFFD geometric modeling method suitable for assembled thin-walled component structures, which fundamentally solves the modeling robustness problem of gaps and overlaps between thin-walled components due to the lack of accurate topological consistency in traditional modeling methods. The unified expression form of the design models, analysis models and optimization models based on the isogeometric paradigm, provides a new tool for optimization design of engineering thin-walled structures, and is expected to greatly improve product design accuracy and shorten development cycle. A multi-level nested composite spline structure in MNFFD allows deformation to be transferred between the thin-walled components, so that the geometric dimension reduction transformation from 3D design domain to 2D design domain is realized, the problem of adaptive updating of a design model is solved, and the design domain decoupling of an assembled thin-walled component structure with a complex assembly relationship is realized. All the above factors make the geometric modeling of the thin-walled structure based on MNFFD have more obvious advantages in refined and integrated design than explicit splines and discrete meshes. The present invention is expected to be one of the main geometric modeling methods for assembled thin-walled component structures in the fields of aerospace, ship, automobile, civil construction, sports safety, etc.

Finally, it should be noted that the above embodiments are only used for describing the technical solution of the present invention rather than limiting the present invention. Although the present invention is described in detail by referring to the above embodiments, those ordinary skilled in the art should understand that: the amendments to the technical solution recorded in each of the above embodiments or the equivalent replacements for part of or all the technical features therein do not enable the essence of the corresponding technical solution to depart from the scope of the technical solution of various embodiments of the present invention.

1. An adaptive geometric modeling method for assembled thin-walled component structures oriented to integration of modeling, analysis and optimization, comprising the following steps:
step 100: using a multi-level NURBS-based free-form deformation (MNFFD) technique to realize accurate geometric modeling of an assembled thin-walled component structure;
step 200: establishing a modeling-analysis unified model suitable for isogeometric analysis of the assembled thin-walled component structure based on an MNFFD method;
step 300: establishing a modeling-analysis-design unified model suitable for collaborative design of a shape and a stiffened layout of the assembled thin-walled component structure based on the MNFFD method.

2. The adaptive geometric modeling method for assembled thin-walled component structures oriented to integration of modeling, analysis and optimization according to claim 1, wherein the step 100 comprises the following sub-steps:
step 101: using a NURBS-based free-form deformation (NFFD) technique to establish implicit characterization relationships of a complex thin-walled structural assembly, including the following two mapping relationships: first, embedding a NURBS curve into a parameter space of a NURBS curved surface, i.e., mapping from a 2D parameter space R² (ξ₁, ξ₂) to a 3D physical space R³ (x, y, z); second, embedding a NURBS curved surface into a parameter space of a NURBS solid, i.e., mapping from a 3D parameter space R³ (ξ₁, ξ₂, ξ₃) to a 3D physical space R³ (x, y, z); by embedding an object into the parameter space of the NURBS curved surface or the NURBS solid, the implicit geometric definitions of the curve in the curved surface and the curved surface in the solid are obtained;
step 102: allowing multi-level and composite mapping of a structure and proposing the MNFFD method according to the two mapping relationships mentioned in step 101 on the basis of an original NFFD method of single-level mapping to establish the implicit characterization relationships of the assembled thin-walled component structure based on MNFFD; the multi-level mapping relationship of MNFFD enables a nested model to satisfy assembly relationships and geometric constraints between different thin-walled components, and finally realize accurate geometric modeling of the assembled thin-walled component structure.

3. The adaptive geometric modeling method for assembled thin-walled component structures oriented to integration of modeling, analysis and optimization according to claim 1, wherein the step 200 comprises the following sub-steps:
Step 201: deriving theoretical formulas of a 6-degree-of-freedom degenerated shell element and a 6-degree-of-freedom degenerated beam element based on an MNFFD mapping model according to an isogeometric paradigm;
step 202: establishing a coupling relationship of NURBS curved surface patches by a domain decomposition method in isogeometric analysis based on MNFFD to realize propagation of solutions between curved surfaces or mapping curved surfaces.

4. The adaptive geometric modeling method for assembled thin-walled component structures oriented to integration of modeling, analysis and optimization according to claim 3, wherein the domain decomposition method in the step 202 includes a penalty method, a Lagrange multiplier method and a Nitsche's method.

5. The adaptive geometric modeling method for assembled thin-walled component structures oriented to integration of modeling, analysis and optimization according to claim 1, wherein the step 300 comprises the following sub-steps:
step 301: in optimization design of a thin-walled structure, establishing a modeling-analysis-design integrated model based on the MNFFD method, transforming a design space from a 3D physical space to a 2D or 3D standard parameter space, and conducting collaborative optimization of a shape and a stiffened layout of a shell; with respect to shape optimization of the assembled thin-walled component structure, using a mapping curved surface in an MNFFD model to represent a skin, a ribbed plate, a stiffener or other structures, embedding the mapping curved surface into a 3D NURBS solid, changing a shape of a surrounding NURBS solid by moving control points thereof or modifying a weight value, and transferring deformation directly to an object geometry represented by the mapping curved surface;
step 302: in the design of the stiffened layout of the assembled thin-walled component structure, conducting parametric design of the stiffened layout in two parts: optimization of shapes of stiffener curves and optimization of stiffened layout; the shapes of the stiffener curves are defined by quadratic NURBS mapping curves, and each curve is represented by at least three control points; with respect to a spacing of a stiffener curve family, a geometric series function is defined to represent the spacing among the control points of the stiffener curves.
